(19) United States
(12) Patent Application Publication
(10) Pub. No.: US 2004/0149225 A1
(43) Pub. Date: Aug. 5, 2004

(54) Process and apparatus for depositing plasma coating onto a container

(76) Inventors: Christopher M. Weikart, Midland, MI (US); Paul J. O'Connor, Midland, MI (US); Ing-Feng Hu, Midland, MI (US)

Correspondence Address: THE DOW CHEMICAL COMPANY, INTELLECTUAL PROPERTY SECTION, P. O. BOX 1967, MIDLAND, MI, 48641-1967, US

(21) Appl. No.: 10/705,599

(22) Filed: Nov. 10, 2003

Related U.S. Application Data
(60) Provisional application No. 60/425,990, filed on Nov. 12, 2002.
(60) Provisional application No. 60/462,093, filed on Apr. 10, 2003.

(51) Int. Cl. B05D 7/22; C23C 16/00; C23C 16/24

(52) U.S. Cl. 118/723 MW; 427/569; 427/237; 427/255.393

(57) ABSTRACT

The present invention describes a method and an apparatus for plasma coating the inside surface of a container to provide an effective barrier against gas transmission. The method provides a way to deposit rapidly and uniformly very thin and nearly defect-free layers of polyorganosiloxane and silicon oxide on the inner surface of a container to achieve more than an order of magnitude increase in barrier properties.

This application claims the benefit of U.S. Provisional Application No. 60/425,990, filed Nov. 12, 2002 and U.S. Provisional Application No. 60/462,093 filed on Apr. 10, 2003.

### BACKGROUND OF THE INVENTION

The present invention relates to a process and an apparatus for depositing a plasma-generated coating onto a container, more particularly onto the inside surface of a container, preferably a plastic container.

Plastic containers have been used to package carbonated and non-carbonated beverages for many years. Plastics such as polyethylene terephthalate (PET) and polypropylene (PP) are preferred by consumers because they resist breakage, and they are light-weight and transparent. Unfortunately, the shelf-life of the beverage is limited in plastics due to relatively high O₂ and CO₂ permeability.

Efforts to treat plastic containers so as to impart low O₂ and CO₂ permeability are known. For example, Laurent et al. (WO 9917333) describes using plasma enhanced chemical vapor deposition (PECVD) to coat the inside surface of a plastic container with an SiOₓ layer. In general, SiOₓ coatings provide an effective barrier to gas transmission; nevertheless, SiOₓ is insufficient to form an effective barrier to gas transmission for plastic containers.

In U.S. Pat. No. 5,641,559, Namiki describes deposition of a plasma polymerized silicic compound onto the outer surface of PET and PP bottles, followed by deposition of a SiOₓ layer. The thickness of the polymerized silicic compound ranges from 0.01 to 0.1 μm and the thickness of the SiOₓ layer ranges from 0.03 to 0.2 μm. Although Namiki discloses that the combination of the plasma polymerized silicic compound and the SiOₓ layer (where x is 1.5 to time of the layers is on the order of 15 minutes, which is impractical for commercial purposes. Moreover, the process described by Namiki is disadvantaged because much of the plasma polymerized monomer is deposited in places other than the desired substrate. This undesired deposition results in inefficient precursor-to-coating conversion, contamination, equipment fouling, and non-uniformity of coating of the substrate.

It would, therefore, be desirable to discover a process for rapidly coating a container uniformly, particularly a plastic container, to provide an effective barrier against gas transmission and to reduce contamination.

### SUMMARY OF THE INVENTION

The present invention addresses a problem in the art by providing a process for preparing a protective barrier for a container having an internal surface comprising the steps of a) plasma polymerizing under partial vacuum and in an oxygen-rich atmosphere a first organosilicon compound under conditions to deposit a polyorganosiloxane layer of uniform thickness onto the internal surface of the container; and b) plasma polymerizing under partial vacuum a second organosilicon compound under conditions to deposit a silicon oxide layer superposing the same or a different polyorganosiloxane layer.

In a second aspect, the present invention is an improved apparatus for depositing a plasma-generated coating onto a surface of a container, which apparatus has: a) an external conducting resonant cylinder having a cavity, an inside, and an outside; b) a generator capable of providing an electromagnetic field in the microwave region connected to the outside of the resonant cavity; c) a wave guide situated between the external conducting resonant cylinder and the generator, which wave guide is capable of directing microwaves to the inside of the external conducting resonant cylinder; d) a cylindrical tube that is transparent to microwaves disposed within the external conducting resonant cylinder, which tube is closed on one end and open on the other end to permit the introduction of a container; e) at least one electrically conductive plate situated in the resonant cavity; and e) a cover for the open end; wherein the improvement comprises an injector fitted to the cover, which injector is porous, coaxial, longitudinally reciprocating, or rotating about its longitudinal axis, or a combination thereof, which injector is insertable into a container so as to extend at least partially into the container.

### BRIEF DESCRIPTION OF THE INVENTION

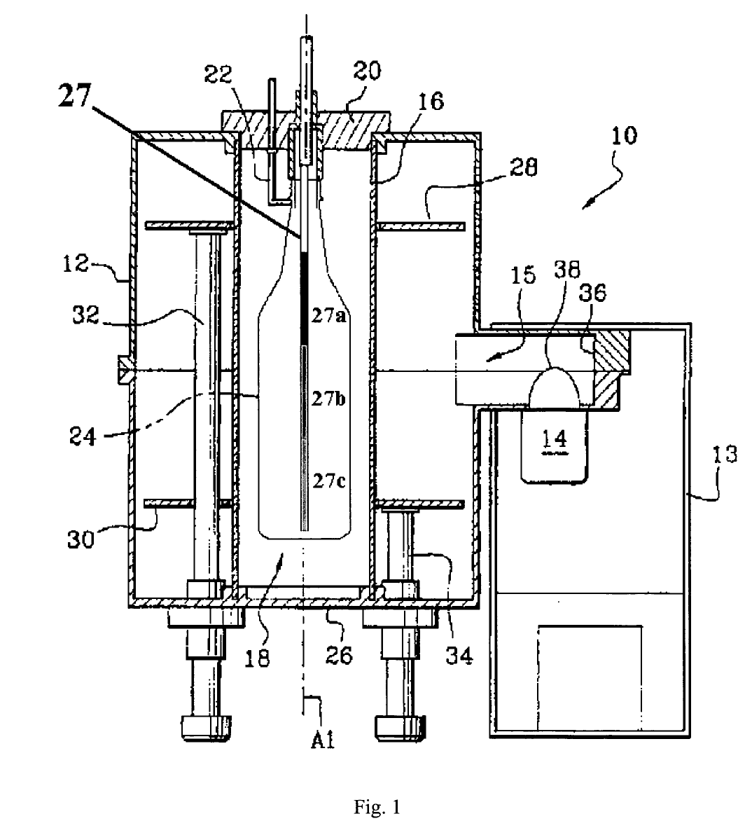

FIG. 1 is an illustration of an apparatus used to coat the inside of a container.

### DETAILED DESCRIPTION OF THE INVENTION

The process of the present invention is advantageously, though not uniquely, carried out using an apparatus described in WO0066804, which is reproduced with some modification in FIG. 1. The apparatus 10 has an external conducting resonant cavity 12, which is preferably cylindrical (also referred to as an external conducting resonant cylinder having a cavity). Apparatus 10 includes a generator 14 that is connected to the outside of resonant cavity 12. The generator 14 is capable of providing an electromagnetic field in the microwave region, more particularly, a field corresponding to a frequency of 2.45 GHz. Generator 14 is mounted on box 13 on the outside of resonant cavity 12 and the electromagnetic radiation it delivers is taken up to resonant cavity 12 by a wave guide 15 that is substantially perpendicular to axis A1 and which extends along the radius of the resonant cavity 12 and emerges through a window located inside the resonant cavity 12.

Tube 16 is a hollow cylinder transparent to microwaves located inside resonant cavity 12. Tube 16 is closed on one end by a wall 26 and open on the other end to permit the introduction of a container 24 to be treated by PECVD. Container 24 may be made from any non-electrically conductive material including glass, ceramics, composites, and plastics. Container 24 is preferably a plastic such as a polyalkylene terephthalates including polyethylene terephthalate and polybutylene terephthalate; polyolefins including polypropylenes and polyethylenes; polycarbonates; polyvinyl chlorides; polyethylene naphthalates; a polyvinylidene chlorides; polyamides including nylon; polystyrenes; polyurethanes; epoxies; acrylics including polymethylmethacrlate; and polylactic acids.

The open end of tube 16 is then sealed with cover 20 so that a partial vacuum can be pulled on the space defined by tube 16 to create a reduced partial pressure on the inside of container 24. The container 24 is held in place at the neck by a holder 22 for container 24. Partial vacuum is advantageously applied to both the inside and the outside of container 24 to prevent container 24 from being subjected to too large a pressure differential, which could result in deformation of container 24. The partial vacuums of the inside and outside of the container are different, and the partial vacuum maintained on the outside of the container is set so as not to allow plasma formation onto the outside of container 24 where deposition is undesired. Preferably, a partial vacuum in the range of from about 20 μbar to about 200 μbar is maintained for the inside of container 24 and a partial vacuum of from about 20 mbar to about 100 mbar, or less than 10 μbar, is pulled on the outside of the container 24.

Cover 20 is adapted with an injector 27 that is fitted into container 24 so as to extend at least partially into container 27 to allow introduction of reactive fluid that contains a reactive monomer and a carrier. Injector 27 can be designed to be, for example, porous, open-ended, longitudinally reciprocating, rotating, coaxial, and combinations thereof. As used herein, the word “porous” is used in the traditional sense to mean containing pores, and also broadly refers to all gas transmission pathways, which may include one or more slits. A preferred embodiment of injector 27 is an open-ended porous injector, more preferably an open-ended injector with graded—that is, with different grades or degrees of—porosity, which injector extends preferably to almost the entire length of the container. The pore size of injector 27 preferably increases toward the base of container 24 so as to optimize flux uniformity of activated precursor gases on the inner surface of container 24. FIG. 1 illustrates this difference in porosity by different degrees of shading, which represent that the top third of the injector 27a has a lower porosity than the middle third of the injector 27b, which has a lower porosity than the bottom third of the injector 27c. The porosity of injector 27 generally ranges on the order of 0.5 μm to about 1 mm. However, the gradation can take a variety of forms from stepwise, as illustrated, to truly continuous. The cross-sectional diameter of injector 27 can vary from just less than the inner diameter of the narrowest portion of container 24 (generally from about 40 mm) to about 1 mm.

The apparatus 10 also includes at least one electrically conductive plate in the resonant cavity to tune the geometry of the resonant cavity to control the distribution of plasma in the interior of container 24. More preferably, though not essentially, as illustrated in FIG. 1, the apparatus 10 includes two annular conductive plates 28 and 30, which are located in resonant cavity 12 and encircle tube 16. Plates 28 and 30 are displaced from each other so that they are axially attached on both sides of the tube 16 through which the wave guide 15 empties into resonant cavity 12. Plates 28 and 30 are designed to adjust the electromagnetic field to ignite and sustain plasma during deposition. The position of plates 28 and 30 can be adjusted by sliding rods 32 and 34.

Deposition of polyorganosiloxane and SiOₓ layers can be accomplished as follows. A mixture of gases including a balance gas and a working gas (together, the total gas mixture) is flowed through injector 27 at such a concentration and power density, and for such a time to create coatings with desired gas barrier properties.

As used herein, the term “working gas” refers to a reactive substance, which may or may not be gaseous at standard temperature and pressure, that is capable of polymerizing to form a coating onto the substrate. Examples of suitable working gases include organosilicon compounds such as silanes, siloxanes, and silazanes. Examples of silanes include tetramethylsilane, trimethylsilane, dimethylsilane, methylsilane, dimethoxydimethylsilane, methyltrimethoxysilane, tetramethoxysilane, methyltriethoxysilane, diethoxydimethylsilane, methyltriethoxysilane, triethoxyvinylsilane, tetraethoxysilane (also known as tetraethylorthosilicate or TEOS), dimethoxymethylphenylsilane, phenyltrimethoxysilane, 3-glycidoxypropyltrimethoxysilane, glycidoxypropyltrimethoxysilane, 3-methacrylpropyltrimethoxysilane, diethoxymethylphenylsilane, tris(2-methoxyethoxy)vinylsilane, phenyltriethoxysilane, and dimethoxydiphenylsilane. Examples of siloxanes include tetramethyldisiloxane, hexamethyldisiloxane, and octamethyltrisiloxane. Examples of silazanes include hexamethylsilazanes and tetramethylsilazanes. Siloxanes are preferred working gases, with tetramethyldisiloxane (TMDSO) being especially preferred.

As used herein, the term “balance gas” is a reactive or non-reactive gas that carries the working gas through the electrode and ultimately to the substrate. Examples of suitable balance gases include air, O₂, CO₂, NO, N₂O as well as combinations thereof. Oxygen (O₂) is a preferred balance gas.

In a first plasma polymerizing step, a first organosilicon compound is plasma polymerized in an oxygen rich atmosphere on the inner surface of the container, which may or may not be previously subjected to surface modification, for example, by roughening, crosslinking, or surface oxidation. As used herein, the term “oxygen-rich atmosphere” means that the balance gas contains at least about 20% oxygen, more preferably at least about 50% oxygen. Thus, for the purposes of this invention, air is a suitable balance gas, but N₂ is not.

The quality of the polyorganosiloxane layer is virtually independent of the mole percent ratio of balance gas to the total gas mixture up to about 80 mole percent of the balance gas, at which point the quality of the layer degrades substantially. The power density of the plasma for the preparation of the polyorganosiloxane layer is preferably greater than 10 MJ/kg, more preferably greater than 20 MJ/kg, and most preferably greater than 30 MJ/kg; and preferably less than 1000 MJ/kg, more preferably less than 500 MJ/kg, and most preferably less than 300 MJ/kg.

In this first step, the plasma is sustained for preferably less than 5 seconds, more preferably less than 2 seconds, and most preferably less than 1 second; and preferably greater than 0.1 second, and more preferably greater than 0.2 second to form a polyorganosiloxane coating having a thickness of preferably less than 500 Å, more preferably less than 200 Å, and most preferably less than 100 Å; and preferably greater than 25 Å, more preferably greater than 50 Å.

Preferably the first plasma polymerizing step is carried out at a deposition rate of less than about 500 Å/sec, more preferably less than 200 Å/sec, and preferably greater than 50 Å/sec, and more preferably greater than 100 Å/sec.

The preferred chemical composition of the polyorganosiloxane layer is SiOₓC_{y}H_{z}, where x is in the range of 1.0 to 2.4, y is in the range of 0.2 to 2.4, and z is greater than or equal to 0, more preferably not more than 4.

In the second plasma polymerizing step, a second organosilicon compound, which may be the same as or different from the first organosilicon compound, is plasma polymerized to form a silicon oxide layer on the polyorganosiloxane layer described above, or a different polyorganosiloxane layer. In other words, it is possible, and sometimes advantageous, to have more than one polyorganosiloxane layer of different chemical compositions. Preferably, the silicon oxide layer is an SiOₓ layer, where x is in the range of 1.5 to 2.0.

For the second plasma polymerizing step, the mole ratio of balance gas to the total gas mixture is preferably about stoichiometric with respect to the balance gas and the working gas. For example, where the balance gas is oxygen and the working gas is TMDSO, the preferred mole ratio of balance gas to total gas is 85% to 95%. The power density of the plasma for the preparation of the silicon oxide layer is preferably greater than 10 MJ/kg, more preferably greater than 20 MJ/kg, and most preferably greater than 30 MJ/kg ; and preferably less than 500 MJ/kg, and more preferably less than 300 MJ/kg.

In this second step, the plasma is sustained for preferably less than 10 seconds, and more preferably less than 5 seconds, and preferably greater than 1 second to form a silicon oxide coating having a thickness of less than 500 Å, more preferably less than 300 Å, and most preferably less than 200 Å, and preferably greater than 50 Å, more preferably greater than 100 Å.

Preferably, the second plasma polymerizing step is carried out at a deposition rate of less than about 500 Å/sec, more preferably less than 200 Å/sec, and preferably greater than 50 Å/sec, and more preferably greater than 100 Å/sec.

The total thickness of the first and second plasma polymerized layers is preferably less than 1000 Å, more preferably less than 500 Å, more preferably less than 400 Å, and most preferably less than 300 Å, and preferably greater than 100 Å. The total plasma polymerizing deposition time (that is, the deposition time for the first and the second layers) is preferably less than 20 seconds, more preferably less than 10 seconds, and most preferably less than 5 seconds.

Surprisingly, it has been discovered that very thin coatings of uniform thickness can be rapidly deposited on the inner surface of a container to create a barrier to the permeation of small molecules such O₂ and CO₂. As used herein, the word “uniform thickness” refers to a coating that has less than a 25% variance in thickness throughout the coated region. Preferably, the coating is virtually free of cracks or foramina. Preferably, the barrier improvement factor (BIF, which is the ratio of the transmission rate of a particular gas for the untreated bottle to the treated bottle) is at least 10, more preferably, at least 20.

The following example is for illustrative purposes only and is not intended to limit the scope of the invention.

### EXAMPLE

### Preparation of a Plasma Coating on a PET Bottle

An apparatus illustrated in FIG. 1 is used for this example. In this example, container 24 is a 500 mL PET bottle suitable for carbonated beverages. Bottle 24 is inserted into tube 16, which is located in resonant cavity 12. Cover 12 is adapted with an open-ended graded porous injector 27 that is fitted into bottle 24 so that injector 27 extends to about 1 cm from the bottom of bottle 24. Injector 27 is fabricated by welding together three sections of 2.5″ long (6.3 cm) porous hollow stainless steel tubing (0.25″ outer diameter (0.64 cm), 0.16″ inner diameter (0.41 cm)), each tubing with a different porosity, to form a single 7.5″ (19 cm) graded injector as illustrated in FIG. 1. The top third of injector 27a has a pore size of about 20 μm, the middle third of the injector 27b has a pore size of about 30 μm, and the bottom third of the injector 27c has a pore size of about 50 μm. (Porous tubing available from Mott, Corp.)

A partial vacuum is established on both the inside and the outside of bottle 24. The outside of bottle 24 is maintained at 80 mbar and the inside is maintained initally at about 10 μbars. An organosiloxane layer is deposited uniformly on the inside surface of bottle 24 as follows. TMDSO and O₂ are each flowed together through injector 27 at the rate of 10 sccm, thereby increasing the partial pressure of the inside of the container. Once the partial pressure reaches 40 μbars (generally, less than 1 second), power is applied at 150 W (corresponding to a power density of 120 MJ/kg) for about 0.5 seconds to form an organosiloxane layer having a thickness of about 50 Å.

An SiOₓ layer is deposited uniformly over the organosiloxane layer as follows. TMDSO and O₂ are flowed together through injector 27 at rates of 10 sccm and 80 sccm, respectively, thereby increasing the partial pressure of the inside of bottle 24. Once the partial pressure reaches 60 μbars (generally, less than 1 second), power is applied at 350 W (corresponding to a power density of 120 MJ/kg) for about 3.0 seconds to form an SiOₓ layer having a thickness of about 150 Å.

Barrier performance is indicated by a barrier improvement factor (BIF), which denotes the ratio of the oxygen transmission rate of the uncoated bottle to the coated bottle. The BIF is measured using an Oxtran 2/20 oxygen transmission device (available from Mocon, Inc.) to be 27, which corresponds to an oxygen transmission rate of 0.0017 cm³/bottle/day.

What is claimed is:

1. A process for preparing a protective barrier for a container having an internal surface comprising the steps of:
a) plasma polymerizing under partial vacuum and in an oxygen-rich atmosphere a first organosilicon compound under conditions to deposit a polyorganosiloxane layer of uniform thickness onto the internal surface of the container; and
b) plasma polymerizing under partial vacuum a second organosilicon compound under conditions to deposit a silicon oxide layer of uniform thickness superposing the same or a different polyorganosiloxane layer.

2. The process of claim 1 wherein plasma polymerizing steps are carried out at such power densities and concentrations of the first and second organosilicon compounds and for such a time so that the combined thickness of the polyorganosiloxane and silicon oxide layers is less than 400 Å.

3. The process of claim 1 wherein the first plasma polymerizing step is carried out at a deposition rate of greater than 50 Å/sec and less than 500 Å/sec and the second plasma polymerizing step is carried out at a deposition rate of greater than 10 and less than 100 Å/sec.

4. The process of claim 1 wherein the first plasma polymerizing step is carried out at a deposition rate of greater than 100 Å/sec and less than 200 Å/sec and the second plasma polymerizing step is carried out at a deposition rate of not less 30 Å/sec and not greater 60 Å/sec.

5. The process of claim 3 wherein the total plasma polymerizing deposition time is not more than 10 seconds.

6. The process of claim 1 wherein the polyorgansiloxane is represented by the formula SiOₓC_{y}H_{z}, where x is in the range of 1.0 to 2.4, y is in the range of 0.2 to 2.4, and z is not more than 4, and the silicon oxide layer is represented by the formula SiOₓ, where x is from 1.5 to 2.0.

7. The process of claim 1 wherein the container comprises a plastic selected from the group consisting of a polyalkylene terephthalate, a polyolefin, and a polylactic acid.

8. The process of claim 7 wherein the plastic is selected from the group consisting of a polyethylene terephthalate, a polyethylene, and a polypropylene.

9. The process of claim 1 wherein the oxygen and the first and second organosilicon compounds are fed through an injector which is porous, open-ended, longitudinally reciprocating, rotating, coaxial, or combinations thereof.

10. The process of claim 9 wherein the oxygen and the first and second organosilicon compounds are fed through an open-ended porous injector positioned within the container and extending almost the length of the container.

11. The process of claim 10 wherein the porous injector is a graded porous injector, wherein porosity increases toward the base of the container.

12. The process of claim 11 wherein porosity increases in a stepwise fashion.

13. The process of claim 11 wherein porosity increases in a continuous fashion.

14. The process of claim 11 wherein the inside and the outside of the container are both maintained at a partial vacuum, wherein the partial vacuum of the outside of the container is set a) so as not to allow plasma formation on the outside of the container; and b) so as to be different from the partial vacuum on the inside of the container.

15. The process of claim 14 wherein the partial vacuum on the inside of the container is in the range of about 20 μbar to about 200 μbar, and the partial vacuum on the outside of the container is 20 μbar to about 100 μbar or less than 10 μbar.

16. In an improved apparatus for depositing a plasma-generated coating onto a surface of a container, which apparatus has:
a) an external conducting resonant cylinder having a cavity, an inside, and an outside;
b) a generator capable of providing an electromagnetic field in the microwave region connected to the outside of the resonant cavity;
c) a wave guide situated between the external conducting resonant cylinder and the generator, which wave guide is capable of directing microwaves to the inside of the external conducting resonant cylinder;
d) a cylindrical tube that is transparent to microwaves disposed within the external conducting resonant cylinder, which tube is closed on one end and open on the other end to permit the introduction of a container;
e) at least one electrically conductive plate situated in the resonant cavity; and
f) a cover for the open end; wherein the improvement comprises an injector fitted to the cover, which injector is porous, coaxial, longitudinally reciprocating, or rotating about its longitudinal axis, or a combination thereof, which injector is insertable into a container so as to extend at least partially into the container.

17. The apparatus of claim 16 wherein the injector is porous and open-ended.

18. The apparatus of claim 17 wherein the injector is a graded porous injector, wherein the porosity increases toward the open-ended portion.

19. The apparatus of claim 18 wherein the porosity increases in a stepwise fashion.

20. The apparatus of claim 18 wherein the porosity increases in a continuous fashion.
